(19) United States
(12) Patent Application Publication
(10) Pub. No.: US 2025/0351349 A1
(43) Pub. Date: Nov. 13, 2025

(54) THREE-DIMENSIONAL MEMORY DEVICE AND METHOD FOR FORMING THE SAME

(71) Applicant: Winbond Electronics Corp., Taichung City (TW)

(72) Inventor: Han-Huei Hsu, Changhua County (TW)

(73) Assignee: Winbond Electronics Corp., Taichung City (TW)

(21) Appl. No.: 18/824,135

(22) Filed: Sep. 4, 2024

(30) Foreign Application Priority Data
May 7, 2024 (TW) 113116844

(51) Int. Cl. H10B 43/27

(52) U.S. Cl. CPC H10B 43/27

(57) ABSTRACT

A three-dimensional (3D) memory device is provided. The three-dimensional memory device includes a stacked structure disposed on a substrate and includes first insulating layers and first conductive layers arranged in an alternating manner in a first direction. The stacked structure has arcuate sidewall regions and linear sidewall regions arranged in an alternating manner in a second direction. The second direction is perpendicular to the first direction. The three-dimensional memory device also includes a charge storage structure and second conductive layers. The charge storage structure conformally covers the arcuate sidewall regions and the linear sidewall regions of the stacked structure. The second conductive layers are separated from each other and cover the charge storage structure, so that the charge storage structure is sandwiched between the second conductive layers and the stacked structure.

### CROSS REFERENCE TO RELATED APPLICATIONS

This application claims priority of Taiwan Patent Application No. 113116844 filed on May 7, 2024, entitled “THREE-DIMENSIONAL MEMORY DEVICE AND METHOD FOR FORMING THE SAME”, the entirety of which is incorporated by reference herein.

### BACKGROUND OF THE INVENTION

### Field of the Invention

The invention relates to a semiconductor structure, and in particular to a three-dimensional memory device having a self-aligned/self-isolated channel or gate, and a method of forming the same.

### Description of the Related Art

The data stored in a volatile memory device is erased when the power is removed. Unlike volatile memory devices, data stored in non-volatile memory devices is retained when power is removed.

A flash memory device is a non-volatile memory device that not only retains data when the power is removed, but also has the property of being able to perform multiple write/erase operations. Therefore, flash memory devices have become popular storage devices. However, as electronic products and semiconductor devices become smaller in size, the manufacture of flash memory devices still face some challenges.

For example, vertical gate/channels are often formed by using a patterning process (including photolithography and etching processes), which makes small-sized gate/channels susceptible to breaking or bridging with neighboring gate/channels, thereby reducing the reliability of the gate/channel. Therefore, it is difficult to increase or improve the yield of the memory device.

### BRIEF SUMMARY OF THE INVENTION

Embodiments of the present disclosure provide a three-dimensional memory device and a method for forming the same. The three-dimensional memory device has self-aligned/self-isolated channel layers or gate layers that have a uniform width, thereby improving device yields and simplifying process steps.

The three-dimensional memory device includes a stacked structure that is disposed on a substrate and includes a plurality of first insulating layers and a plurality of first conductive layers arranged in an alternating manner in a first direction. The stacked structure has a plurality of arcuate sidewall regions and a plurality of linear sidewall regions arranged in an alternating manner in a second direction. The second direction is perpendicular to the first direction. The three-dimensional memory device also includes a charge storage structure and a plurality of second conductive layers. The charge storage structure conformally covers the arcuate sidewall regions and the linear sidewall regions of the stacked structure. The second conductive layers are spaced apart from each other and cover the charge storage structure, so that the charge storage structure is sandwiched between the second conductive layers and the stacked structure.

The method of forming a three-dimensional memory device includes alternately stacking a plurality of first insulating layers and a plurality of first conductive layers on a substrate in a first direction, and then patterning the plurality of first insulating layers and the plurality of first conductive layers to form at least one stacked structure. The stacked structure has a plurality of first sidewall surfaces and a plurality of second sidewall surfaces arranged in an alternating manner in a second direction. The second direction is perpendicular to the first direction. The first sidewall surfaces have different contours than the plurality of second sidewall surfaces, as viewed from a top-view perspective. The method also includes forming a charge storage structure on the plurality of first sidewall surfaces and on the plurality of second sidewall surfaces. The method further includes forming a plurality of second conductive layers on the charge storage structure corresponding to the plurality of first sidewall surfaces, so that the charge storage structure is sandwiched between the plurality of second conductive layers and the stacked structure.

Each of the stacked structures includes sidewall regions with different contours (e.g., straight and arcuate contours, as viewed from a top-view perspective) that are arranged in an alternating manner. As a result, self-aligning/self-isolated channel layers or gate layers can be formed on the sidewall regions having straight or arcuate contours during the manufacturing process of the three-dimensional memory device, thereby preventing from breaking or bridging of these channel layers or gate layers during the fabrication process. Therefore, the reliability of the channel layers or gate layers is increased. Furthermore, the formation of the self-aligned/self-isolated channel layers or gate layers eliminates the need to form an additional electrical isolation layer between adjacent self-aligned/self-isolated channel layers or gate layers, which simplifies the process steps and reduces the manufacturing cost.

### BRIEF DESCRIPTION OF THE DRAWINGS

FIGS. 1A to 1E and 2A to 2D are perspective diagrams showing a method of forming a three-dimensional memory device in accordance with some embodiments.

FIGS. 1E-1 and 2D-1 are perspective diagrams showing a three-dimensional memory device in accordance with some embodiments.

### DETAILED DESCRIPTION OF THE INVENTION

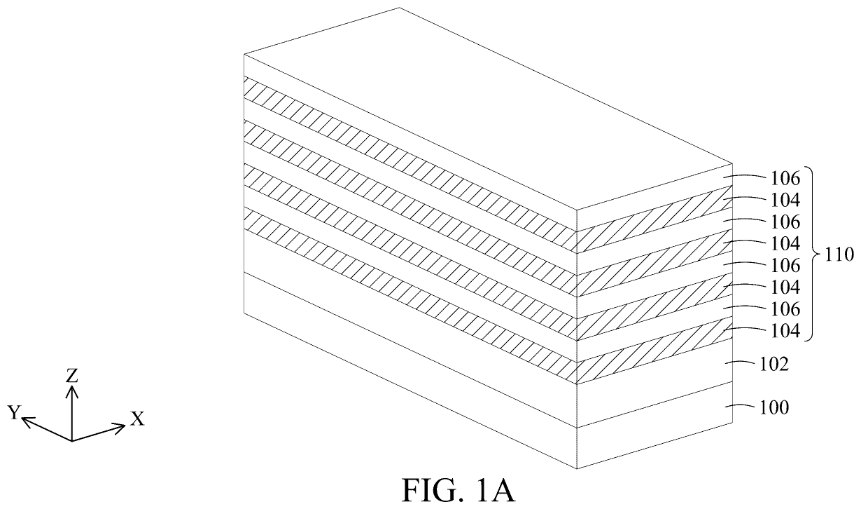

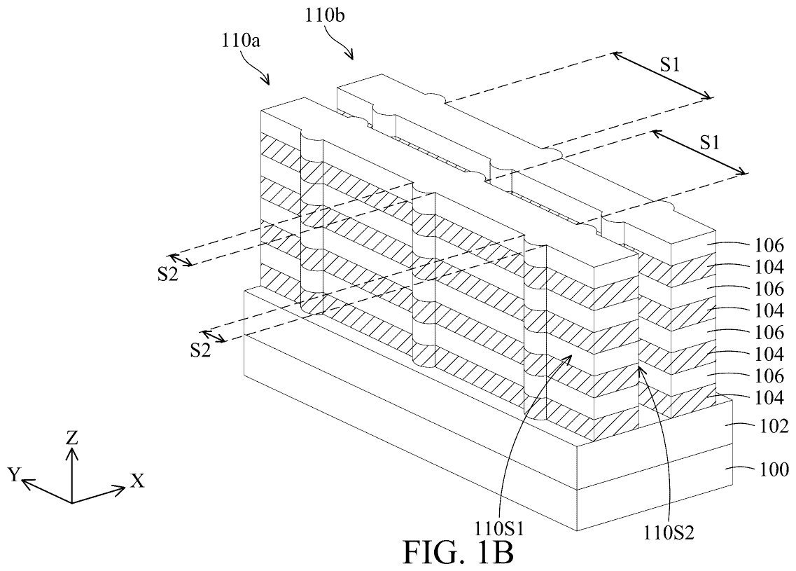

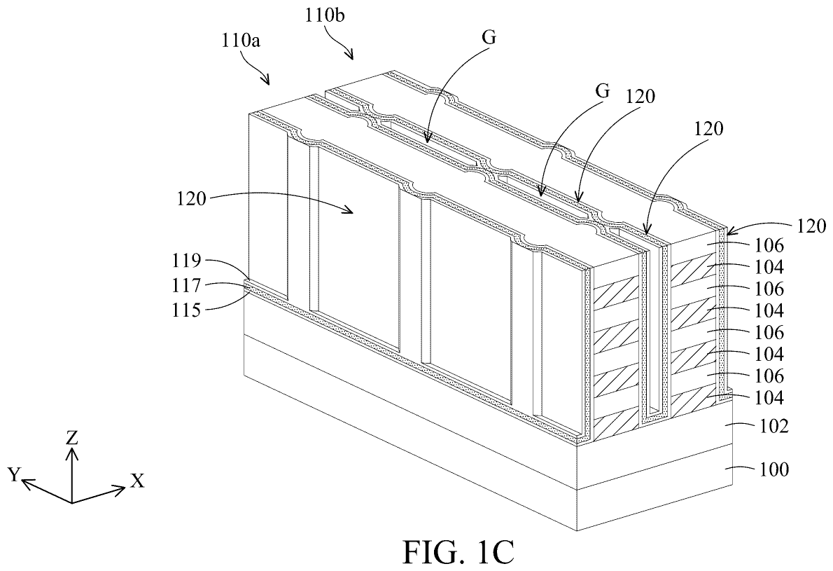

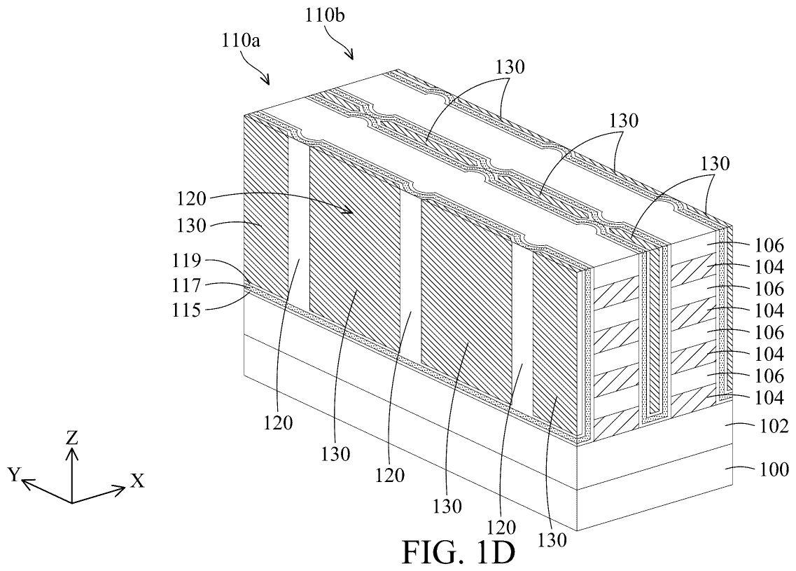

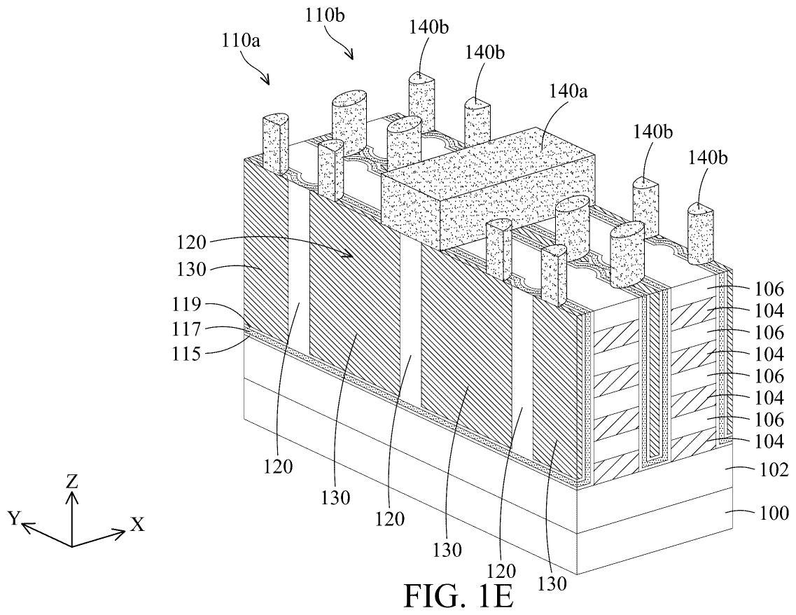

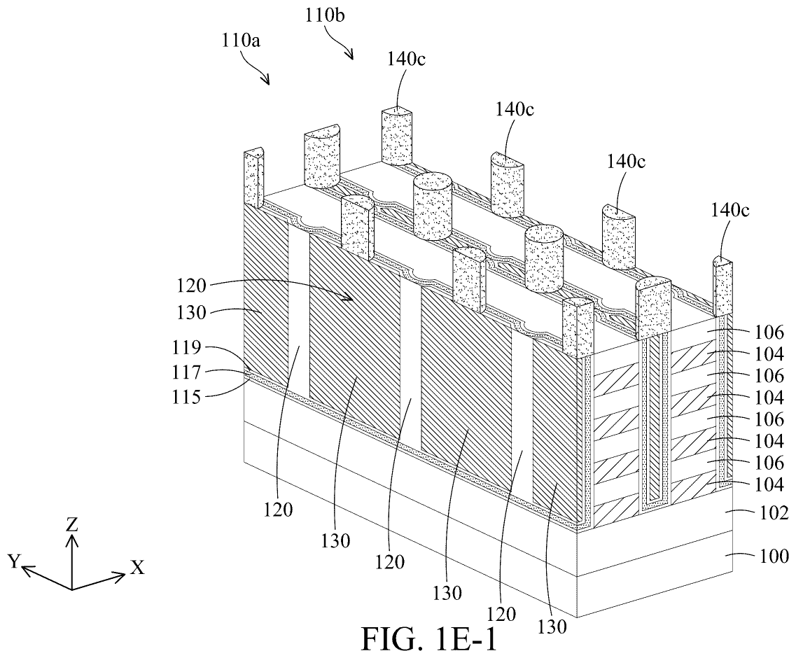

FIGS. 1A to 1E are perspective diagrams showing a method of forming a three-dimensional memory device in accordance with some embodiments. Referring to FIG. 1A, a semiconductor substrate 100 is provided, and an insulating layer 102 is optionally formed on the semiconductor substrate 100 to serve as an electrical isolation layer between the semiconductor substrate 100 and the memory device subsequently formed thereon. Accordingly, the insulating layer 102 may also be referred to as an electrical isolation layer. The electrical isolation layer may include a silicon oxide layer, a silicon nitride layer, a silicon oxynitride layer, a silicon oxycarbide layer, or the like, or a combination thereof. The insulating layer 102 may be formed using a chemical vapor deposition (CVD) process, an atomic layer deposition (ALD) process, or other suitable deposition processes.

Afterwards, insulating layers 106 and conductive layers 104 are alternately stacked on a first direction (e.g., a direction perpendicular to the upper surface of the semiconductor substrate 100, such as the Z-direction shown in FIG. 1A) on the insulating layer 102 over the semiconductor substrate 100, the bottommost layer of the stack is the conductive layer 104 and the topmost layer is the insulating layer 106, as shown in FIG. 1A. Both the bottommost and topmost layers of the stack may be the insulating layers 106, and such the bottommost layer of the stack can be utilized in place of the insulating layer 102 as the electrical isolation layer between the subsequently formed memory device and the semiconductor substrate 100.

The conductive layer 104 includes a metal material (e.g., copper, aluminum, tungsten, titanium, tantalum or the like, or alloys thereof), a metal silicide material (e.g., tungsten silicide or the like), a polysilicon material, or another suitable conductive material. The insulating layer 106 includes a silicon oxide layer, a silicon nitride layer, a silicon oxynitride layer, a silicon oxycarbide layer, or the like or a combination thereof. The conductive layer 104 may be formed using a chemical vapor deposition process, an atomic layer deposition process, a spin-coating process, or other suitable deposition processes, while the insulating layer 106 may be formed using a CVD process, an ALD process, a physical vapor deposition (PVD) process, or other suitable deposition processes.

Referring to FIG. 1B, a stack 110 including the insulating layers 106 and the conductive layers 104 is patterned to form one or more stacked structures, the stack is patterned by using a photolithography process and an etching process (e.g., dry or wet etching process). For example, the photolithography process and etching process are employed to form a patterned hard mask layer (not shown) on the topmost layer of the stack (e.g., the insulating layer 106), and then the patterned hard mask layer is used as an etching mask to transfer the pattern into the stack 110 that includes the insulating layers 106 and the conductive layers 104, so as to form the stacked structures. In order to simplify the diagram, herein only two adjacent stacked structures 110a and 110b are depicted. The stacked structures 110a and 110b are spaced apart from each other in one direction (e.g., the X direction shown in FIG. 1B).

The stacked structures 110a and 110b each have first sidewall surfaces S1 and second sidewall surfaces S2 arranged in an alternating manner in the second direction (e.g., a direction parallel to an upper surface of the semiconductor substrate 100, such as the Y direction shown in FIG. 1B) perpendicular to the first direction. Two opposite sides (first side 110S1 and second side 110S2) of each of the stacked structures 110a and 110b have linear sidewall regions and arcuate sidewall regions that are arranged in an alternating manner. Each linear sidewall region has a first sidewall surface S1 on the two opposite sides (first side 110S1 and second side 110S2) of the stacked structure (e.g., stacked structure 110a or 110b), and each arcuate sidewall region has a second sidewall surface S2 on the two opposite sides (first side 110S1 and second side 110S2) of the stacked structure (e.g., stacked structure 110a or 110b). The first sidewall surfaces S1 each have a straight contour parallel to the second direction (i.e., the Y direction), and the second sidewall surfaces S2 each have a convex contour protruding from the straight contour of the first sidewall surfaces S1, as viewed from a top-view perspective. As a result, a recess is formed between the two adjacent second sidewall surfaces S2 that are recessed into the stacked structures 110a and 110b in the X direction, and the bottom of the recess is the first sidewall surface S1. Therefore, the two adjacent recesses are separated by the second sidewall surfaces S2.

Referring to FIG. 1C, a charge storage structure 120 is conformally formed on the two opposite sides (first side 11051 and second side 11052) of each of the stacked structures 110a and 110b to cover the first sidewall surfaces S1 and the second sidewall surfaces S2, the charge storage structure 120 includes a single-layer or multi-layer structure. For example, the charge storage structure 120 is a multi-layer structure and the fabrication of the charge storage structure 120 includes: conformally forming an insulating layer 115 to cover the upper surface of the insulating layer 102 that is exposed from the stacked structures 110a and 110b, each of the first sidewall surfaces S1, each of the second sidewall surfaces S2, and the upper surfaces of the stacked structures 110a and 110b. Next, a charge storage layer 117 is conformally formed on the insulating layer 115. Afterwards, an insulating layer 119 is conformally formed on the charge storage layer 117. The charge storage structure 120 may be a multilayer structure that includes a silicon oxide layer/a silicon nitride layer/a silicon oxide layer (oxide-nitride-oxide, ONO). That is, the insulating layers 115 and 119 are made of silicon oxide (SiO₂) and the charge storage layer 117 is made of silicon nitride (Si₃N₄). The insulating layer 115, the charge storage layer 117, and the insulating layer 119 can be formed sequentially by a CVD process, an ALD process, a PVD process, or other suitable deposition processes. The polysilicon material can be used as the material of the charge storage layer 117.

Afterwards, a planarization process (such as a chemical mechanical polishing (CMP) process or a grinding process) may be optionally performed on the charge storage structure 120 to remove portions of the charge storage structure 120 above the upper surfaces of the stacked structures 110a and 110b, so as to expose the upper surfaces of the topmost layers (i.e., insulating layers 106) of the stacked structures 110a and 110b, when the distance between the stacked structures 110a and 110b is sufficiently small, the insulating layer 119 between the second sidewall surface S2 of the stacked structure 110a and the second sidewall surface S2 of the stacked structure 110b may be contacted or merged together, so that the recesses of the stacked structure 110a and the corresponding recesses of the stacked structure 110b form gaps G (also referred to as self-aligned openings) surrounded by the insulating layers 119.

Referring to FIG. 1D, conductive layers 130 are formed on the charge storage structure 120 corresponding to the first sidewall surface S1, so that the charge storage structure 120 is sandwiched between the conductive layers 130 and the stacked structures 110a and 110b. The conductive layers 130 are formed on the upper surfaces of the topmost layers of the stacked structures 110a and 110b (i.e., insulating layer 106) and the charge storage structure 120 over the upper surfaces of the insulating layer 102, and fill the gaps G.

Afterwards, a planarization process (e.g., a CMP process or a grinding process) may be performed on the conductive layers 130 to remove portions of the conductive layers 130 above the upper surfaces of the stacked structures 110a and 110b to expose the upper surfaces of the topmost layers (i.e., the insulating layers 106) of the stacked structures 110a and 110b. The planarization process is not performed after the formation of the charge storage structures 120 and before the formation of the conductive layers 130, and is performed after the formation of the conductive layers 130 until the upper surfaces of the topmost layers (i.e., the insulating layer 106) of the stacked structures 110a and 110b are exposed. As a result, each gap G has a self-aligned conductive layer 130 therein, and the self-aligned conductive layers 130 are separated from each other by the insulating layers 119 formed on the second sidewall surfaces S2. Therefore, the self-aligned conductive layers 130 are also referred to as self-isolated conductive layers. The material and fabrication used for the conductive layer 130 may be the same as or similar to those used for the conductive layer 104, and the material and fabrication used for the conductive layer 130 may be different from those used for the conductive layer 104.

The three-dimensional memory device has vertical channel layers. In this case, each conductive layer 104 act as a gate line of the three-dimensional memory device, and each conductive layer 130 acts as a channel layer (or channel region) of the three-dimensional memory device.

Referring to FIG. 1E, after the formation of the conductive layer 130, a source-contact plug 140a and a drain-contact plug 140b are correspondingly formed on the upper surfaces of the conductive layers 130 (channel region), and are electrically connected to them. The source-contact plug 140a is a common source-contact plug, which is electrically connected to channel regions. As shown in FIG. 1E, the formed three-dimensional memory device at least includes stacked structures 110a and 110b, charge storage structures 120, conductive layers 130, a source-contact plug 140a, drain-contact plugs 140b, and an optional insulating layer (electrical isolation layer) 102.

Stacked structures 110a and 110b are disposed on a substrate 100 and include insulating layers 106 and conductive layers 104 (gate lines) that are arranged in an alternating manner in a first direction (e.g., Z direction). The stacked structures 110a and 110b each have arcuate sidewall regions and linear sidewall regions (such as first sidewall surfaces S1 and second sidewall surfaces S2 shown in FIG. 1B) that are arranged in an alternating manner in a second direction (e.g., Y direction) that is perpendicular to the first direction. The charge storage structures 120 conformally cover the arcuate sidewall regions and the linear sidewall regions of the stacked structures 110a and 110b. The conductive layers 130 (channel regions) are spaced apart from each other and cover the charge storage structures 120. For example, the conductive layers 130 are correspondingly disposed on the charge storage structures 120 that cover the linear sidewall regions (first sidewall surfaces S1). The charge storage structures 120 that are sandwiched between the conductive layers 130 and the corresponding stacked structures 110a and 110b each include an insulating layer 115, an insulating layer 119, and a charge storage layer 117 sandwiched between the insulating layers 115 and 119. The insulating layers 115 are in direct contact with the stacked structures 110a and 110b, while the insulating layers 119 are in direct contact with the conductive layers 130. The source-contact plug 140a and the drain-contact plug 140b are correspondingly disposed on the upper surfaces of the conductive layers 130, and are electrically connected to them. The insulating layer 102 (electrical isolation layer) is disposed between the substrate 100 and the stacked structures 100a and 100b, and between the substrate 100 and the conductive layers 130, in which the charge storage structure 120 extends between the insulating layer 102 and the conductive layers 130.

Each stacked structure includes sidewall regions having different contours (e.g., sidewall regions having a straight contour and sidewall regions having a convex contour) arranged in an alternating manner. Accordingly, self-aligned openings can be formed between adjacent stacked structures by the sidewall regions having the convex contour, and then a self-aligned/self-isolated channel layer can be formed in the self-aligned opening. As a result, breaking or bridging of these channel layers during the fabrication process can be prevented, thereby increasing the reliability of the channel layers and the yield of the memory device. Furthermore, since the self-aligned openings are separated from each other by the insulating layer formed on the sidewall regions having the convex contour, there is no need to form an additional electrical isolation layer between the adjacent self-aligned/self-isolated channel layers, thereby simplifying the process steps and reducing the manufacturing cost. In addition, the formed self-aligned/self-isolated channel layers have a uniform width, which helps to improve the electrical properties of the memory device.

Referring to FIG. 1E-1, which is a perspective diagram showing a three-dimensional memory device in accordance with some embodiments. Elements in FIG. 1E-1 that are the same as those in FIG. 1E are labeled with the same reference numbers as in FIG. 1E and may not described again for brevity. The structure and fabrication of the three-dimensional memory device shown in FIG. 1E-1 are similar to the structure and fabrication of the three-dimensional memory device shown in FIG. 1E, and thus the three-dimensional memory device shown in FIG. 1E-1 has the same or similar benefits as the three-dimensional memory device shown in FIG. 1E. Unlike the three-dimensional memory device shown in FIG. 1E, the three-dimensional memory device shown in FIG. 1E-1 has a vertical gate. In this case, each conductive layer 104 acts as a channel layer (or channel region) of the three-dimensional memory device, and each conductive layer 130 acts as a gate line of the three-dimensional memory device.

Referring to FIGS. 1E-1, after the formation of the conductive layer 130, a gate-contact plug 140c is formed on the upper surface of the gate line, and is electrically connected to it. A self-aligned/self-isolated gate line is formed in the self-aligned opening. As a result, breaking or bridging of these gate lines during formation can be prevented, thereby increasing the reliability of the gate lines and the yield of the memory device. Furthermore, the formed self-aligned/self-isolated gate lines have a uniform width, which helps to improve the electrical properties of the memory device.

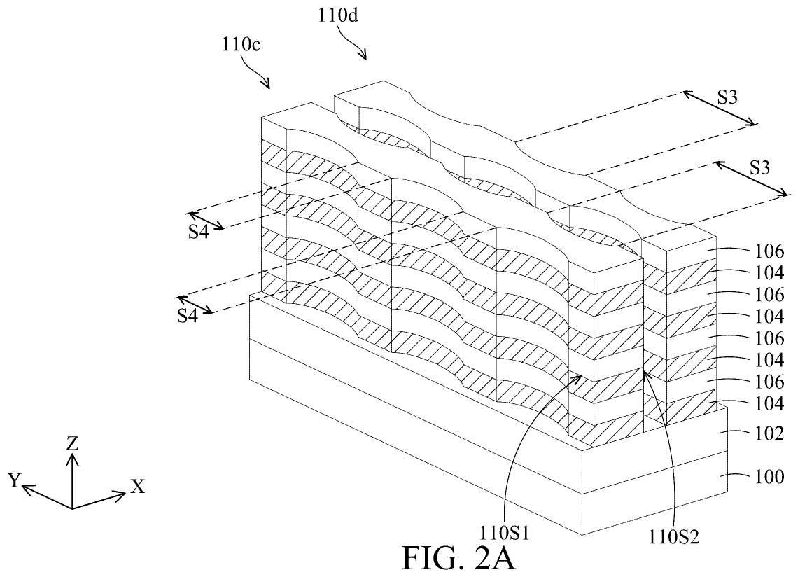

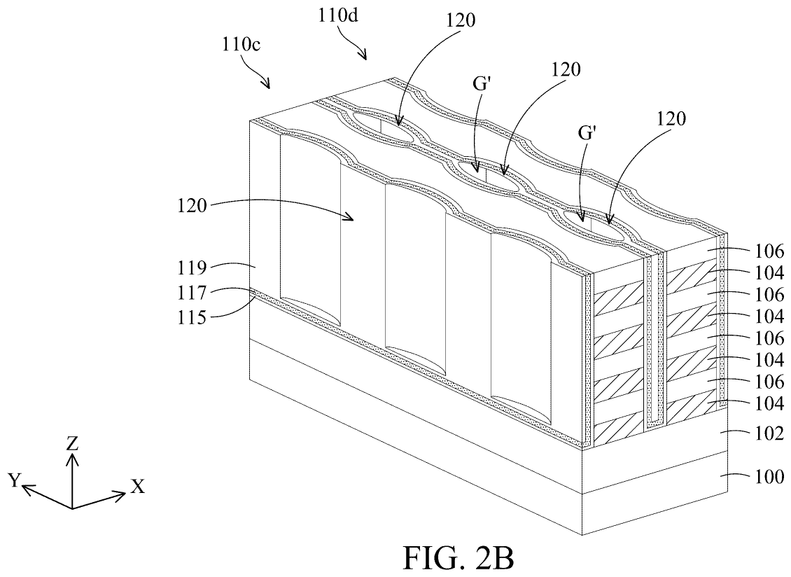

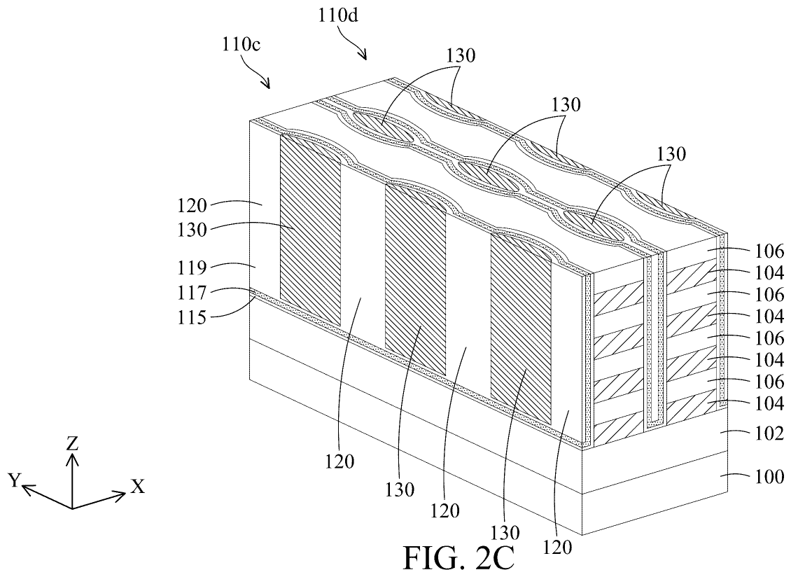

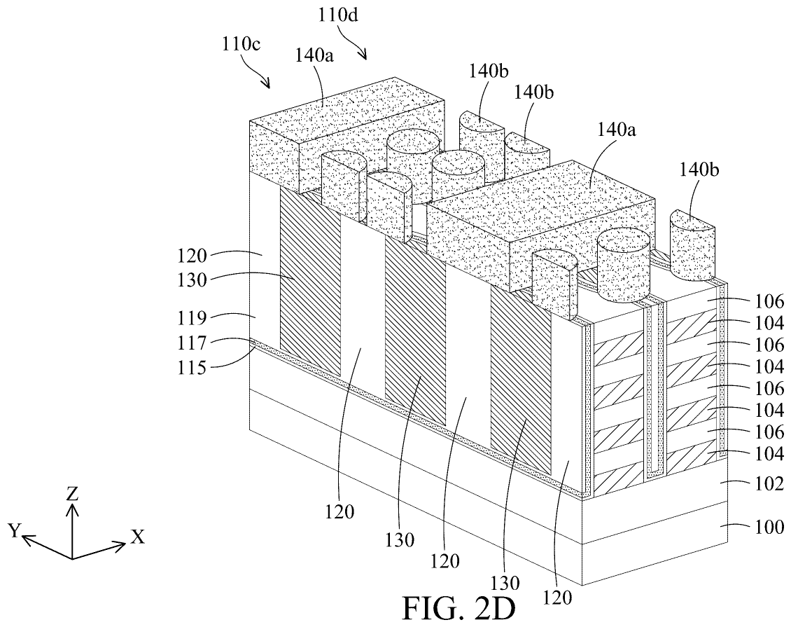

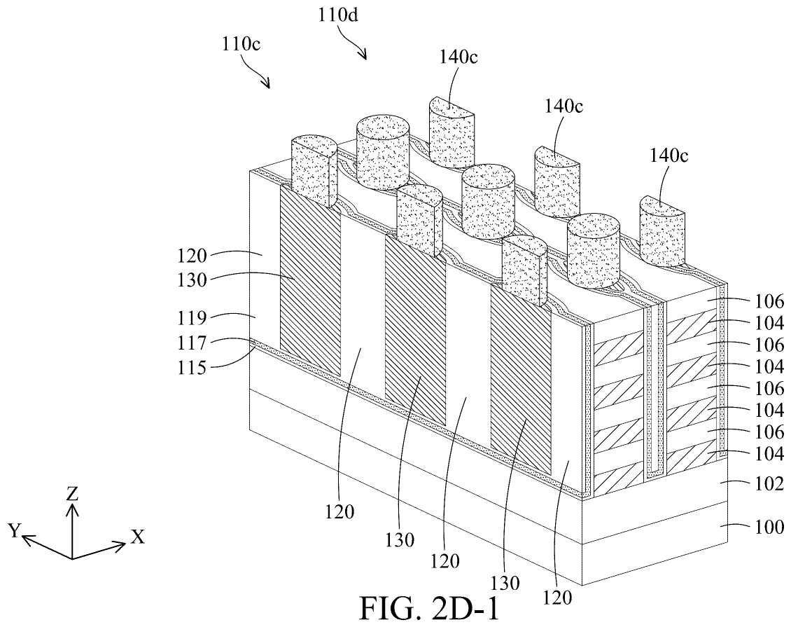

FIGS. 2A to 2D are perspective diagrams showing various stages of a process for forming a three-dimensional memory device in accordance with some embodiments. Elements in FIGS. 2A to 2D that are the same as those in FIGS. 1A to 1E are labeled with the same reference numbers as in FIGS. 1A to 1E and may not described again for brevity. Referring to FIG. 2A, a structure as shown in FIG. 1A is provided. Afterwards, a stack 110 including insulating layers 106 and conductive layers 104 is patterned to form one or more stacked structures. Such a stack is patterned by using a photolithography process and an etching process (e.g., dry or wet etching process) to form the stacked structures. In order to simplify the diagram, herein only two adjacent stacked structures 110c and 110d are depicted.

Unlike the stacked structures 110a and 110b shown in FIG. 1B, the stacked structure 110c and 110d are formed by patterning the stack 110 that includes the insulating layers 106 and the conductive layers 104. The stacked structures 110c and 110d each have arcuate sidewall regions and linear sidewall regions arranged in an alternating manner in the Y-direction. The two opposing sides (first side 110S1 and second side 110S2) of the arcuate sidewall regions have a first sidewall surface S3, and the two opposing sides (first side 110S1 and second side 110S2) of the linear sidewall regions have a second sidewall surface S4. The first sidewall surfaces S3 each have a concave contour recessed into the stacked structure 110c or 110d, and the second sidewall surfaces S4 each have a straight contour parallel to the Y direction, as viewed from a top-view perspective. As a result, a recess is formed between two adjacent second sidewall surfaces S4 recessed into the stacked structure 110c or 110d in the X direction, and the bottom of the recess is the first sidewall surface S3. Therefore, the two adjacent recesses are separated by the second sidewall surface S4.

Referring to FIG. 2B, a charge storage structure 120 is conformally formed on the respective two opposite sides (the first side 110S1 and the second side 110S2) of the stacked structure 110c or 110d, so as to cover the first sidewall surfaces S3 and the second sidewall surfaces S4.

Afterwards, the optional planarization process as described in FIG. 1C may be performed on the charge storage structure 120. When the distance between the stacked structures 110c and 110d is sufficiently small, the insulating layer 119 between the second sidewall surfaces S2 of the stacked structure 110c and the second sidewall surface S2 of the stacked structures 110d may be contacted or merged together, so as to form gaps G′ (also referred to as self-aligned openings) surrounded by the insulating layers 119). The gaps G′ are similar to the gaps G (as shown in FIG. 1C).

Referring to FIG. 2C, conductive layers 130 are formed on the charge storage structures 120 corresponding to the first sidewall surfaces S3, so that the charge storage structures 120 are sandwiched between the conductive layers 130 and the stacked structures 110c and 110d. The conductive layers 130 are formed on the upper surfaces of the topmost layers of the stacked structures 110c and 110d (i.e., insulating layer 106) and the charge storage structure 120 over the upper surfaces of the insulating layer 102, and fill the gaps G′.

Afterwards, a planarization process as described in FIG. 1D may be performed on the conductive layers 130. The planarization process is not performed after the formation of the charge storage structures 120 and before the formation of the conductive layers 130, and is performed after the formation of the conductive layers 130 until the upper surfaces of the topmost layers (i.e., the insulating layer 106) of the stacked structures 110c and 110d are exposed. As a result, each gap G′ has a self-aligned conductive layer 130 (also referred to as self-isolated conductive layer) therein. The three-dimensional memory device has vertical channel layers. In this case, each conductive layer 104 acts as a gate line of the three-dimensional memory device, and each conductive layer 130 acts as a channel layer (or channel region) of the three-dimensional memory device.

Referring to FIG. 2D, after the formation of the conductive layer 130, a source-contact plug 140a and a drain-contact plug 140b are correspondingly formed on the upper surfaces of the conductive layers 130 (channel region), and are electrically connected to them. The source-contact plug 140a is a common source-contact plug, which is electrically connected to channel regions, as shown in FIG. 2D.

Self-aligned openings can be formed between sidewall regions having a concave contour of a stacked structure and sidewall regions having a concave contour of an adjacent stacked structure. Afterwards, self-aligned/self-isolated channel layers can be formed in the self-aligned openings. As a result, the reliability of the channel layer and the yield of the memory device can be increased. Since it is not necessary to form an additional electrical isolation layer between the adjacent self-aligned/self-isolated channel layers, the process steps can be simplified and the manufacturing cost can be reduced. The formed self-aligned/self-isolated channel layers have a uniform width, which helps to improve electrical properties of the memory device.

Referring to FIG. 2D-1, which is a perspective diagram showing a three-dimensional memory device in accordance with some embodiments. Elements in FIG. 2D-1 that are the same as those in FIG. 2D are labeled with the same reference numbers as in FIG. 2D and may not described again for brevity. The structure and fabrication of the three-dimensional memory device shown in FIG. 2D-1 are similar to the structure and fabrication of the three-dimensional memory device shown in FIG. 2D, and thus the three-dimensional memory device shown in FIG. 2D-1 has the same or similar benefits as the three-dimensional memory device shown in FIG. 2D. Unlike the three-dimensional memory device shown in FIG. 2D, the three-dimensional memory device shown in FIG. 2D-1 has a vertical gate. In this case, each conductive layer 104 acts as a channel layer (or channel region) of the three-dimensional memory device, and each conductive layer 130 acts as a gate line of the three-dimensional memory device. Referring to FIG. 2D-1, after forming the conductive layer 130, a gate contact plug 140c may be correspondingly formed on the upper surface of the gate line, and may be electrically connected to it.

Self-aligned/self-isolated gate lines may be formed within the self-aligned openings. As a result, breaking or bridging of these gate lines during the fabrication process can be prevented, thereby increasing the reliability of the gate lines and the yield of the memory device. Furthermore, the formed self-aligned/self-isolated gate lines have a uniform width, which helps to improve the electrical properties of the memory device. It should be understood that the scope of the present invention is not limited to technical schemes resulting from specific combinations of the above technical features, but should also cover other technical schemes resulting from any combination of the technical features or their equivalent.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A three-dimensional memory device, comprising:
a stacked structure that is disposed on a substrate and comprises a plurality of first insulating layers and a plurality of first conductive layers arranged in an alternating manner in a first direction, wherein the stacked structure has a plurality of arcuate sidewall regions and a plurality of linear sidewall regions arranged in an alternating manner in a second direction perpendicular to the first direction;
a charge storage structure conformally covering the plurality of arcuate sidewall regions and the plurality of linear sidewall regions of the stacked structure; and
a plurality of second conductive layers spaced apart from each other and covering the charge storage structure, so that the charge storage structure is sandwiched between the plurality of second conductive layers and the stacked structure.

2. The three-dimensional memory device as claimed in claim 1, wherein each of the linear sidewall regions has a straight contour that is parallel to the second direction, and each of the arcuate sidewall regions has a convex contour that protrudes from the straight contour, as viewed from a top-view perspective.

3. The three-dimensional memory device as claimed in claim 2, wherein the plurality of second conductive layers is correspondingly disposed on the charge storage structure covering the plurality of linear sidewall regions.

4. The three-dimensional memory device as claimed in claim 1, wherein each of the linear sidewall regions has a straight contour that is parallel to the second direction, and each of the arcuate sidewall regions has a concave contour recessed into the stacked structure, as viewed from a top-view perspective.

5. The three-dimensional memory device as claimed in claim 4, wherein the plurality of second conductive layers are correspondingly disposed on the charge storage structure covering the plurality of arcuate sidewall regions.

6. The three-dimensional memory device as claimed in claim 1, wherein the plurality of first conductive layers acts as a plurality of gate lines of the three-dimensional memory device, and the plurality of second conductive layers acts as a plurality of channel regions of the three-dimensional memory device.

7. The three-dimensional memory device as claimed in claim 6, further comprising:
a plurality of source/drain-contact plugs correspondingly disposed on upper surfaces of the plurality of channel regions and electrically connected them.

8. The three-dimensional memory device as claimed in claim 1, wherein the plurality of second conductive layers acts as a plurality of gate lines of the three-dimensional memory device, and the plurality of first conductive layers acts as a plurality of channel regions of the three-dimensional memory device.

9. The three-dimensional memory device as claimed in claim 8, further comprising:
a plurality of gate-contact plugs correspondingly disposed on upper surfaces of the plurality of gate lines and electrically connected them.

10. The three-dimensional memory device as claimed in claim 1, wherein the charge storage structure comprises:
a second insulating layer in direct contact with the stacked structure;
a third insulating layer in direct contact with the second conductive layers; and
a charge storage layer, sandwiched between the second insulating layer and the third insulating layer.

11. The three-dimensional memory device as claimed in claim 1, further comprising:
an electrical isolation layer disposed between the substrate and the stacked structure, and between the substrate and the plurality of second conductive layers, wherein the charge storage structure extends between the electrical isolation layer and the plurality of second conductive layers.

12. A method for forming a three-dimensional memory device, comprising:
alternately stacking a plurality of first insulating layers and a plurality of first conductive layers in an alternating manner on a substrate in a first direction;
patterning the plurality of first insulating layers and the plurality of first conductive layers to form at least one stacked structure, wherein the stacked structure has a plurality of first sidewall surfaces and a plurality of second sidewall surfaces arranged in an alternating manner in a second direction that is perpendicular to the first direction, and wherein the plurality of first sidewall surfaces and the plurality of second sidewall surfaces have different contours, as viewed from a top-view perspective;
forming a charge storage structure on the plurality of first sidewall surfaces and on the plurality of second sidewall surfaces; and
forming a plurality of second conductive layers on the charge storage structure corresponding to the plurality of first sidewall surfaces, so that the charge storage structure is sandwiched between the plurality of second conductive layers and the stacked structure.

13. The method as claimed in claim 12, wherein the plurality of first sidewall surfaces each have a straight contour parallel to the second direction, and the plurality of second sidewall surfaces each have a convex contour protruding from the straight contour.

14. The method as claimed in claim 12, wherein the plurality of second sidewall surfaces each have a straight contour parallel to the second direction, and the plurality of first sidewall surfaces each have a concave contour recessed into the stacked structure.

15. The method as claimed in claim 12, wherein the plurality of first conductive layers acts as a plurality of gate lines of the three-dimensional memory device, and the plurality of second conductive layers acts as a plurality of channel regions of the three-dimensional memory.

16. The method as claimed in claim 15, further comprising:
correspondingly forming a source/drain-contact plug on the upper surface of the plurality of channel regions and electrically connected it.

17. The method as claimed in claim 12, wherein the plurality of second conductive layers acts as a plurality of gate lines of the three-dimensional memory device, and the plurality of first conductive layers acts as a plurality of channel regions of the three-dimensional memory.

18. The method as claimed in claim 17, further comprising:
forming a gate-contact plug correspondingly on the upper surface of the plurality of gate lines and electrically connected it.

19. The method as claimed in claim 12, wherein forming the charge storage structure comprises:
conformally forming a second insulating layer to cover the plurality of first sidewall surfaces and the plurality of second sidewall surfaces;
conformally forming a charge storage layer on the second insulating layer; and
conformally forming a third insulating layer on the charge storage layer.

20. The method as claimed in claim 17, further comprising:
forming an electrical isolation layer on the substrate before stacking the plurality of first insulating layers and the plurality of first conductive layers in an alternating manner.
